(19) United States
(12) Patent Application Publication
(10) Pub. No.: US 2013/0075934 A1
(43) Pub. Date: Mar. 28, 2013

(54) SEMICONDUCTOR DEVICE

(71) Applicants: Osamu Oto, Kanagawa-ken (JP); Takahiro Tsurudo, Kanagawa-ken (JP); Kenichi Matoba, Kanagawa-ken (JP); Jumpei Sato, Kanagawa-ken (JP)

(72) Inventors: Osamu Oto, Kanagawa-ken (JP); Takahiro Tsurudo, Kanagawa-ken (JP); Kenichi Matoba, Kanagawa-ken (JP); Jumpei Sato, Kanagawa-ken (JP)

(73) Assignee: KABUSHIKI KAISHA TOSHIBA, Minato-ku (JP)

(21) Appl. No.: 13/423,027

(22) Filed: Mar. 16, 2012

(30) Foreign Application Priority Data
Sep. 27, 2011 (JP) 2011-211666

(51) Int. Cl. H01L 23/522

(52) U.S. Cl. 257/775; 257/E23.143

(57) ABSTRACT

In one embodiment, a semiconductor device includes a first wiring provided in a first wiring layer along a first direction, a second wiring provided in a second wiring layer along a second direction orthogonal to the first direction, the second wiring intersecting with the first wiring at a first intersect portion, and a third wiring provided close to and along the second wiring in the second wiring layer, the third wiring intersecting with the first wiring at a second intersect portion, wherein a distance between the second wiring in the first intersection portion and the third wiring in the second intersection portion is narrower than a distance between the second wiring another than the first intersection portion and the third wiring another than the second intersection portion.

### CROSS REFERENCE TO RELATED APPLICATION

This application is based upon and claims the benefit of priority from prior Japanese Patent Application No. 2011-211666, filed on Sep. 27, 2011, the entire contents of which are incorporated herein by reference.

### FIELD

Exemplary embodiments described herein generally relate to a semiconductor device and in particular to the semiconductor device including multi-layer wirings.

### BACKGROUND

Semiconductor devices of recent years have undergone a non-negligible increase in a parasitic capacitance due to the narrowing of the distance between wirings and the thinning of a film between wiring layers along with advancement of micro-fabrication in the manufacturing process. Therefore, a reference potential wiring or the like is provided with shield wirings to reduce the coupling noise from neighboring wirings and thereby to mitigate the negative influence of the noise.

However, in the semiconductor devices, a reference wiring has a non-negligible negative influence of noise from shield wirings set at a fixed potential, when the shield wirings are located too close to the reference wiring.

When a shield wiring is located too close to a signal wiring or a high-voltage line which transmits high-voltage electricity, the parasitic load may increase, leading to an increase in power consumption.

Hence, for some of conventional semiconductor devices, a distance is secured between the shield wiring and the reference wiring or the like. In this regard, in a conventional semiconductor device with a multilayer wiring, a coupling capacitance is increased due to a “sneak path” effect in a portion where a reference wiring, for example, of an upper layer intersects a noise source wiring, for example, of an underlying layer.

Accordingly, the reference potential is affected more by the noise source wiring, and causes a malfunction of the semiconductor device at some timing.

### BRIEF DESCRIPTION OF THE DRAWINGS

FIG. 1 is a layout chart illustrating a semiconductor device according to a first embodiment;

FIG. 2 is a layout chart illustrating a semiconductor device according to a second embodiment;

FIG. 3 is a layout chart illustrating a semiconductor device according to a third embodiment;

FIG. 4 is a layout chart illustrating a semiconductor device according to a fourth embodiment;

FIG. 5 is a layout chart illustrating a semiconductor device according to a fifth embodiment;

FIG. 6 is another layout chart illustrating the semiconductor device according to the fifth embodiment.

FIG. 7 is a layout chart illustrating a semiconductor device combined the first embodiment and the second embodiment;

FIG. 8 is a layout chart illustrating a semiconductor device combined the third embodiment and the fourth embodiment;

FIG. 9 is a layout chart illustrating a semiconductor device according to a modification of the fifth embodiment;

FIG. 10 is a layout chart illustrating a semiconductor device according to the third embodiment and the fifth embodiment; and

FIG. 11 is a layout chart illustrating a semiconductor device combined the fourth embodiment and the fifth embodiment.

### DETAILED DESCRIPTION

In one embodiment, a semiconductor device includes a first wiring provided in a first wiring layer along a first direction, a second wiring provided in a second wiring layer along a second direction orthogonal to the first direction, the second wiring intersecting with the first wiring at a first intersect portion, and a third wiring provided close to and along the second wiring in the second wiring layer, the third wiring intersecting with the first wiring at a second intersect portion, wherein a distance between the second wiring in the first intersection portion and the third wiring in the second intersection portion is narrower than a distance between the second wiring another than the first intersection portion and the third wiring another than the second intersection portion.

Embodiments of the invention will be described with reference to the drawings.

(First Embodiment)

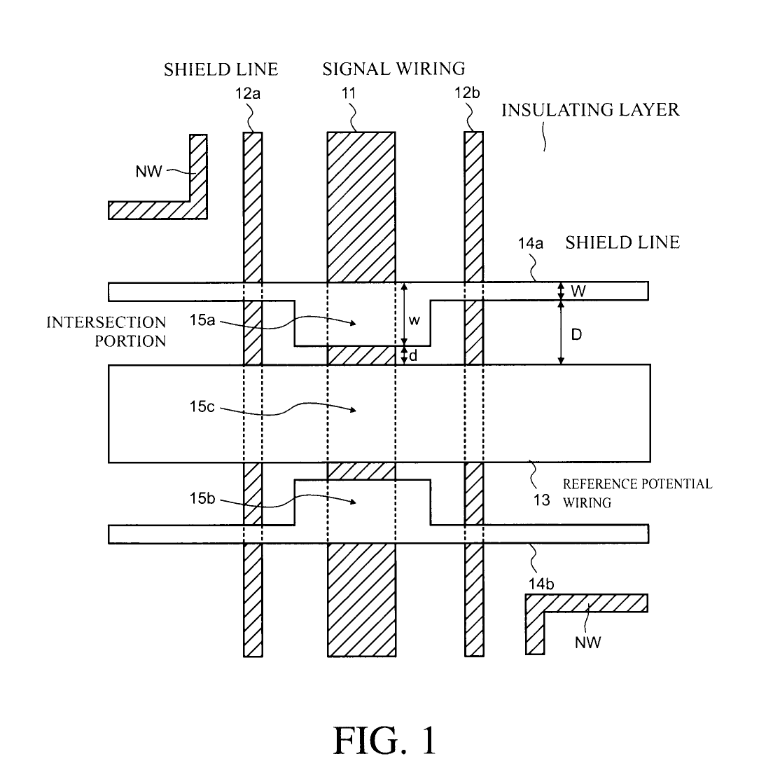

FIG. 1 is a layout chart showing a semiconductor device according to a first embodiment. FIG. 1 mainly shows an example of a reference potential wiring 13 (a reference wiring) and portions related to coupling noise. In addition, FIG. 1 shows only two wiring layers stacked with an insulating layer interposed therebetween among multiple wiring layers, for simplification. The hatched portion in FIG. 1 represents a wiring layout provided in the underlying wiring layer. The underlying wiring layer and the upper wiring layer are covered with insulating films, and have the insulating layer interposed therebetween.

The semiconductor device according to the first embodiment includes shield lines 12a, 12b and a signal wiring 11, all of which are provided in the underlying wiring layer. The semiconductor device also includes a reference potential wiring 13 and shield lines 14a, 14b, all of which are provided in the upper wiring layer.

The signal wiring 11 is provided in the underlying wiring layer and extends in a first direction. The shield lines 12a, 12b are provided in the underlying wiring layer and extend close to and along the signal wiring 11. The two shield lines 12a, 12b are provided respectively on the two sides of the signal wiring 11 in such a manner as to face each other over the signal wiring 11.

The reference potential wiring 13 is provided in the upper wiring layer and extends in a second direction substantially orthogonal to the first direction. The upper wiring layer is located above the underlying wiring layer with an insulating film located in between. To put it differently, the reference potential wiring 13 three-dimensionally intersects with the signal wiring 11 in the underlying layer at an intersection portion 15c with the insulating film located in between.

The shield lines 14a, 14b are provided in the upper wiring layer and extend close to and along the reference potential wiring 13. The two shield lines 14a, 14b are provided respectively on the two sides of the reference potential wiring 13 in such a manner as to face each other over the reference potential wiring 13. As shown in FIG. 1, the shield lines 14a, 14b cross the signal wiring 11 in the underlying layer respectively at intersection portions 15a, 15b with the insulating film located in between. Further, the intersection portions 15a, 15b can be arranged wider or narrower than an overlapped portion with the signal wiring 11 in plane view.

The signal wiring 11 is the wiring which can be a noise source to provide electrical influence as coupling noise to the reference potential wiring 13 via the coupling capacitance at the intersection portion 15c.

The signal wiring 11 can affect or can be affected by other nearby wirings NW provided in the same underlying wiring layer. The shield lines 12a, 12b are provided respectively on the two sides of the signal wiring 11 so as to electrically shield the signal wiring 11 from such other nearby wirings NW. The shield lines 12a, 12b are electrically connected to a fixed potential such as the earth potential Vss.

The reference potential wiring 13 is a wiring to transfer the reference potential which is referred to by various portions in the semiconductor device. The reference potential wiring 13 can be electrically affected by the signal wiring 11 via the coupling capacitance at the intersection portion 15c.

The reference potential wiring 13 can be affected by other nearby wirings NW provided in the same upper wiring layer. The shield lines 14a, 14b are provided respectively on the two sides of the reference potential wiring 13 so as to electrically shield the reference potential wiring 13 from such other nearby wirings. The shield lines 14a, 14b are electrically connected to a fixed potential such as the earth potential Vss. Each of the shield lines 14a, 14b is separated away from the reference potential wiring 13 by a distance D. Even when the potential of the shield line 14a or 14b is fluctuated by the influence of the coupling noise, securing the above-mentioned distance D can prevent the fluctuation in the potential of the shield line 14a or 14b from easily affecting the potential of the reference potential wiring 13. Such a distance D is not secured in the areas near the intersection portions 15a, 15b.

The shield line 14a has a larger wiring width w near the intersection portion 15a of both the shield line 14a and the signal wiring 11 than the wiring width W in other portions (i.e., w>W). Hence, the shield line 14a is separated away from the reference potential wiring 13 by a smaller distance d near the intersection portion 15c than the distance D in the other portions (i.e., d<D). In this case, all portions of shield line 14a with the wide width W can be included in the intersection portion 15a.

The shield line 14b has a larger wiring width w near the intersection portion 15b of both the shield line 14b and the signal wiring 11 than the wiring width W in the other portions (i.e., w>W). Hence, the shield line 14b is separated away from the reference potential wiring 13 by a smaller distance d near the intersection portion 15c than the distance D in the other portions (i.e., d<D). In this case, all portions of shield line 14b with the wide width W can be included in the intersection portion 15b.

As described above, the reference potential wiring 13 is separated away from each of the shield lines 14a, 14b by a narrower distance in the intersection portion 15c of both the signal wiring 11 and the reference potential wiring 13. Hence the line of the electric force which would otherwise be directed from the signal wiring 11 to the reference potential wiring 13 can be directed to the shield lines 14a, 14b, and thus the coupling capacitance of both the signal wiring 11 and the reference potential wiring 13 caused by the sneak path effect can be reduced.

According to the first embodiment, the coupling capacitance is reduced in the intersection portion 15c, so that the influence of the coupling noise between the wirings of the multilayer wirings can be reduced. In addition, the distance between the reference potential wiring 13 and each shield line 19 is widened in the portions other than the intersection portion 15c, so that the influence of the noise from the shield line 14 can be reduced.

In addition, according to the first embodiment, the reduction of the influence of the coupling noise can be accomplished without narrowing any of the reference potential wiring 13 and the signal wiring 11 in the intersection portion 15c. Accordingly, both the resistance of the reference potential wiring 13 and the resistance of the signal wiring 11 can be kept low.

In the first embodiment, the shield lines 14a, 14b are provided respectively on the two sides of the reference potential wiring 13, but the embodiment is not limited to the above case. The embodiment is also applicable to only one of the shield lines.

(Second Embodiment)

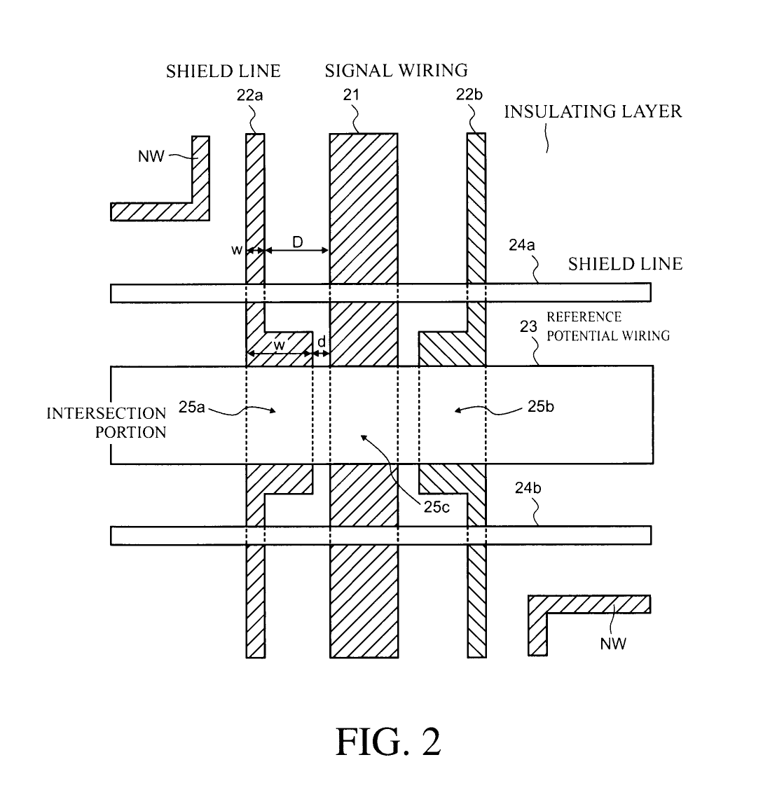

FIG. 2 is a layout chart showing a semiconductor device according to a second embodiment. FIG. 2 mainly shows an example of a reference potential wiring 23 (a reference wiring) and portions of the wiring related to coupling noise Like as FIG. 1. In addition, FIG. 2 shows only the two wiring layers while omitting the insulating films.

The semiconductor device according to the second embodiment includes a signal wiring 21 and shield lines 22a, 22b, all of which are provided on the underlying wiring layer. The semiconductor device also includes a reference potential wiring 23 and shield lines 24a, 24b, all of which are provided in the upper wiring layer.

The signal wiring 21, the reference potential wiring 23, and the shield lines 22a, 22b, 24a, 24b according to the second embodiment have their respective functions and the positional relationship on the layout which are similar to those in the first embodiment. Hence, no detailed description is given of the functions and the positions. The second embodiment is different from the first embodiment in which, instead of the shield lines 24a, 24b provided in the upper wiring layer, the shield lines 22a, 22b provided in the underlying wiring layer are provided more closely to the signal wiring 21 near an intersection portion 25c of both the signal wiring 21 and the reference potential wiring 23.

The shield lines 22a, 22b are provided in the underlying wiring layer and extend close to and along the signal wiring 21. The shield lines 22a, 22b are provided respectively on the two sides of the signal wiring 21 in such a manner as to face each other over the signal wiring 21. As shown in FIG. 2, the shield lines 22a, 22b three-dimensionally cross the reference potential wiring 23 on the upper layer respectively at intersection portions 25a, 25b with the insulating film located in between. Each of the shield lines 22a, 22b is separated away from the signal wiring 21 by a distance D. Even when the potential of the shield line 22a or 22b is fluctuated by the influence of the coupling noise, securing the above-mentioned distance D can prevent the fluctuation in the potential of the shield line 22a or 22b from easily affecting the potential of the signal wiring 21. Such a distance D is not secured in the areas near the intersection portions 25a, 25b.

The shield line 22a has a larger wiring width w near the intersection portion 25a of both the shield line 22a and the reference potential wiring 23 than the wiring width W in e other portions (i.e., w>W). Hence, the shield line 22a is separated away from the signal wiring 21 by a smaller distance d near the intersection portion 25c than the distance Din the other portions (i.e., d<D). In this case, all portions of shield line 22a with the wide width W can be included in the intersection portion 25a.

The shield line 22b has a larger wiring width w near the intersection portion 25b of both the shield line 22b and the reference potential wiring 23 than the wiring width W in the other portions (i.e., w>W). Hence, the shield line 22b is separated away from the signal wiring 21 by a smaller distance d near the intersection portion 25c than the distance D in the other portions (i.e., d<D). In this case, all portions of shield line 22b with the wide width W can be included in the intersection portion 25b.

As described above, the signal wiring 21 is separated away from each of the shield lines 22a, 22b by a narrower distance in the intersection portion 25c of both the signal wiring 21 and the reference potential wiring 23. Hence, the line of the electric force which would otherwise be directed from the reference potential wiring 23 to the signal wiring 21 can be directed to the shield lines 22a, 22b, and thus the coupling capacitance of both the signal wiring 21 and the reference potential wiring 23 caused by the sneak path effect can be reduced. Such a layout is particularly effective when the reference potential wiring 23 is wide and has a long overlapped area with the signal wiring 21 in the intersection portion 25c of both the reference potential wiring 23 and the signal wiring 21.

According to the second embodiment, the coupling capacitance is reduced in the intersection portion 25c, so that the influence of the coupling noise between the wirings of the multilayer wirings can be reduced. In addition, the distance between the signal wiring 21 and each shield line 22 is widened in the portions other than the intersection portion 25c, so that the load capacitance between the signal wiring 21 and each shield line 22 can be reduced.

According to the second embodiment, the reduction of the influence of the coupling noise can be accomplished without narrowing any of the reference potential wiring 23 and the signal wiring 21 in the intersection portion 25c. Accordingly, both the resistance of the reference potential wiring 23 and the resistance of the signal wiring 21 can be kept low.

In the second embodiment, the shield lines 22a, 22b are provided respectively on the two sides of the signal wiring 21, but the invention is not limited to the above case. The invention is also applicable to only one of the shield lines.

(Third Embodiment)

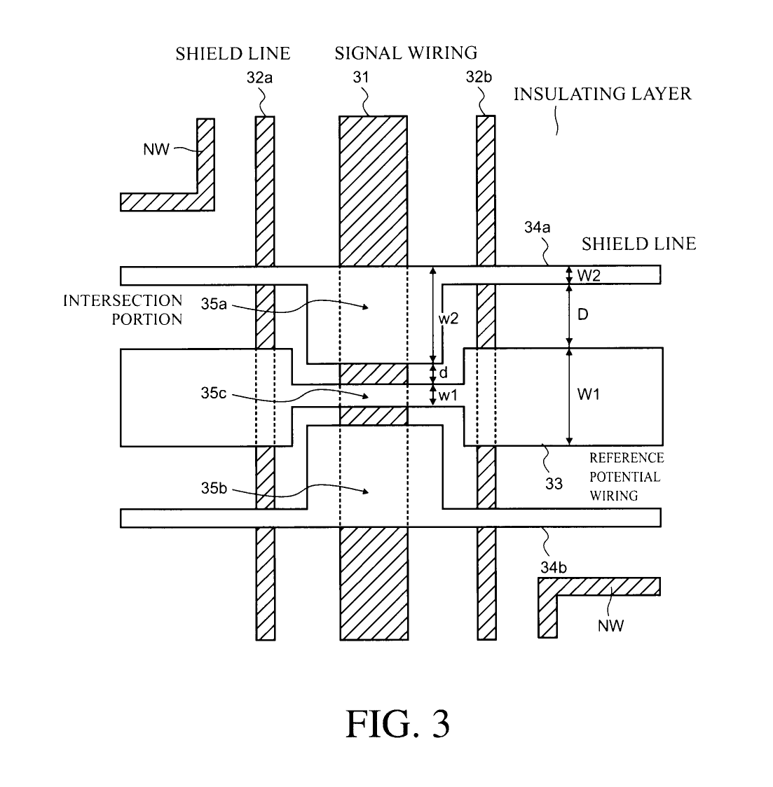

FIG. 3 is a layout chart showing a semiconductor device according to a third embodiment. FIG. 3 mainly shows an example of a reference potential wiring 33 (a reference wiring) and portions of the wiring related to coupling noise Like as FIG. 1. In addition, FIG. 3 shows only the two wiring layers while omitting the insulating films.

The semiconductor device according to the third embodiment includes a signal wiring 31 and shield lines 32a, 32b, all of which are provided on the underlying wiring layer. The semiconductor device also includes a reference potential wiring 33 and shield lines 34a, 34b, all of which are provided on the upper wiring layer.

The signal wiring 31, the reference potential wiring 33, and the shield lines 32a, 32b, 34a, 34b according to the third embodiment have their respective functions and positional relationships on the layout which are similar to those in the first embodiment. Hence, no detailed description is given of the functions and the positions. The third embodiment is different from the first embodiment in which the reference potential wiring 33 provided in the upper wiring layer has a narrower portion near an intersection portion 35c of both the reference potential wiring 33 and the signal wiring 31 than in other portions.

Specifically, as shown in FIG. 3, the reference potential wiring 33 has a smaller wiring width w1 near the intersection portion 35c of both the reference potential wiring 33 and the signal wiring 31 than the wiring width W1 in the other portions (i.e., w1<W1). The wiring width w1 of the reference potential wiring 33 near the intersection portion 35c is set at such a value which the reference potential wiring 33 can have a resistance allowable under a design rule.

The shield line 34a has a larger wiring width w2 near the intersection portion 35a of both the shield line 34a and the signal wiring 31 than the wiring width W2 in the other portions (i.e., w2>W2). Hence, the shield line 34a is separated away from the reference potential wiring 33 by a smaller distance d near the intersection portion 35c than the distance D in the other portions (i.e., d<D). In this case, all portions of shield line 34a with the wide width W2 can be included in the intersection portion 35a.

The shield line 34b has a larger wiring width w2 near the intersection portion 35b of both the shield line 34b and the signal wiring 31 than the wiring width W2 in the other portions (i.e., w2>W2). Hence, the shield line 34b is separated away from the reference potential wiring 33 by a smaller distance d near the intersection portion 35c than the distance D in the other portions (i.e., d<D). In this case, all portions of shield line 34b with the wide width W2 can be included in the intersection portion 35b.

As described above, the signal wiring 31 is separated away from each of the shield lines 34a, 34b by a narrower distance in the intersection portion 35c of both the signal wiring 31 and the reference potential wiring 33. Hence, the line of the electric force which would otherwise be directed from the signal wiring 31 to the reference potential wiring 33 can be directed to the shield lines 34a, 34b. Thus the coupling capacitance of both the signal wiring 31 and the reference potential wiring 33 caused by the sneak path effect can be reduced. In the portions other than the intersection portion 35c, the influence of the noise from each shield line 34 can be reduced by widening the distance between the reference potential wiring 33 and each shield line 34.

Since the reference potential wiring 33 has a smaller wiring width in the intersection portion 35c than in the other portions, the area where the signal wiring 31 and the reference potential wiring 33 overlap each other can be reduced and thus the coupling capacitance can be reduced further.

Such a layout is particularly effective when the signal wiring 31 is wide and has a long overlapped area with the reference potential wiring 33 in the intersection portion 35c.

According to the third embodiment, the influence of the coupling noise between the wirings of the multilayer wirings can be reduced further.

In the third embodiment, the shield lines 34a, 34b are provided respectively on the two sides of the reference potential wiring 33, but the embodiment is not limited to the above case. The embodiment is also applicable to only one of the shield lines.

(Fourth Embodiment)

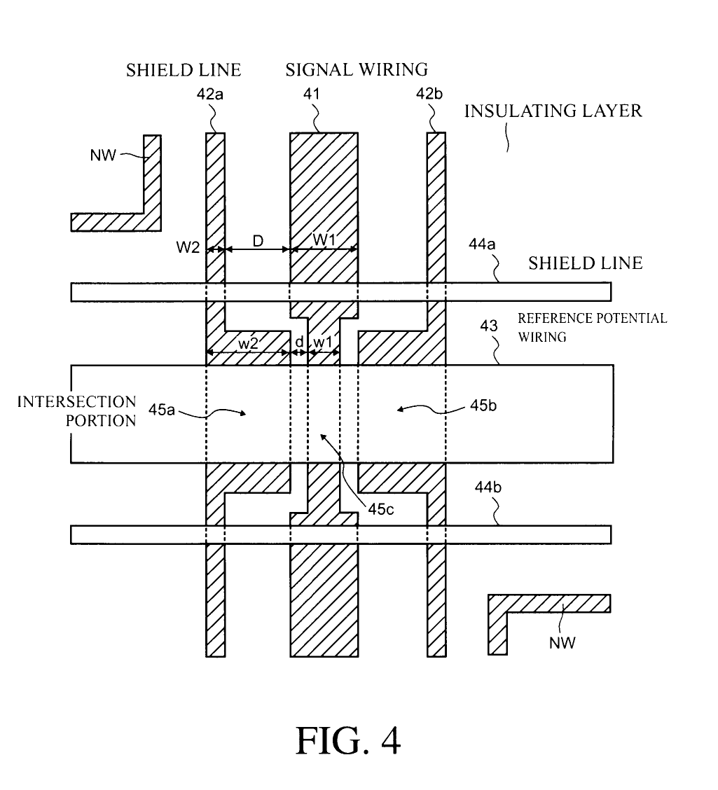

FIG. 4 is a layout chart showing a semiconductor device according to a fourth embodiment. FIG. 4 mainly shows an example of a reference potential wiring 43 (a reference wiring) and portions of the wiring related to coupling noise Like as FIG. 1. In addition, FIG. 4 shows only the two wiring layers while omitting the insulating films.

The semiconductor device according to the fourth embodiment includes a signal wiring 41 and shield lines 42a, 42b, all of which are provided on the underlying wiring layer. The semiconductor device also includes a reference potential wiring 43 and shield lines 44a, 44b, all of which are provided in the upper wiring layer.

The signal wiring 41, the reference potential wiring 43, and the shield lines 42a, 42b, 44a, 44b according to the fourth embodiment have their respective functions and positional relationships on the layout which are similar to those in the second embodiment. Hence, no detailed description is given of the functions and the positions. The fourth embodiment is different from the second embodiment in which the signal wiring 41 provided in the underlying wiring layer has a narrower portion near an intersection portion 45c of both the signal wiring 41 and the reference potential wiring 43 than in other portions.

Specifically, as shown in FIG. 4, the signal wiring has a smaller wiring width w1 near the intersection portion 45c of both the signal wiring 41 and the reference potential wiring 43 than the wiring width W1 in the other portions (i.e., w1<W1). The wiring width w1 of the signal wiring 41 near the intersection portion 45c is set in such a manner which the signal wiring 41 can have a resistance value which is allowable in light of design requirements.

The shield line 42a has a larger wiring width w2 near the intersection portion 45a of both the shield line 42a and the reference potential wiring 43 than the wiring width W2 in the other portions (i.e., w2>W2). Hence, the shield line 42a is separated away from the signal wiring 41 by a smaller distance d near the intersection portion 45c than the distance D in the other portions (i.e., d<D). In this case, all portions of shield line 42a with the wide width W2 can be included in the intersection portion 45a.

The shield line 42b has a larger wiring width w2 near an intersection portion 45b of both the shield line 42b and the reference potential wiring 43 than the wiring width W2 in the other portions (i.e., w2>W2). Hence, the shield line 42b is separated away from the signal wiring 41 by a smaller distance d near the intersection portion 45c than the distance D in the other portions (i.e., d<D). In this case, all portions of shield line 42b with the wide width W2 can be included in the intersection portion 45b.

As described above, the signal wiring 41 is separated away from each of the shield lines 42a, 42b by a narrower distance in the intersection portion 45c of both the signal wiring 41 and the reference potential wiring 43. Hence, the line of the electric force which would otherwise be directed from the reference potential wiring 43 to the signal wiring 41 can be directed to the shield lines 42a, 42b, and thus the coupling capacitance of both the signal wiring 41 and the reference potential wiring 43 caused by the sneak path effect can be reduced. Moreover, in the portions other than the intersection portion 45c, the load capacitance between the signal wiring 41 and each shield line 42 can be reduced by widening the distance between the signal wiring 41 and each shield line 42.

In addition, since the signal wiring 41 has a smaller wiring width in the intersection portion 45c than in the other portions, the area where the signal wiring 41 and the reference potential wiring 43 overlap each other can be reduced and thus the coupling capacitance can be reduced further.

Such a layout is particularly effective when the reference potential wiring 43 is wide and has a long overlapped area with the in the intersection portion 45c of both the reference potential wiring 43 and the signal wiring 41.

According to the fourth embodiment, the influence of the coupling noise between the wirings of the multilayer wirings can be reduced further.

In the fourth embodiment, the shield lines 42a, 42b are provided respectively on the two sides of the signal wiring 41, but the invention is not limited to the above layout. The invention is also applicable to only one of the shield lines.

(Fifth Embodiment)

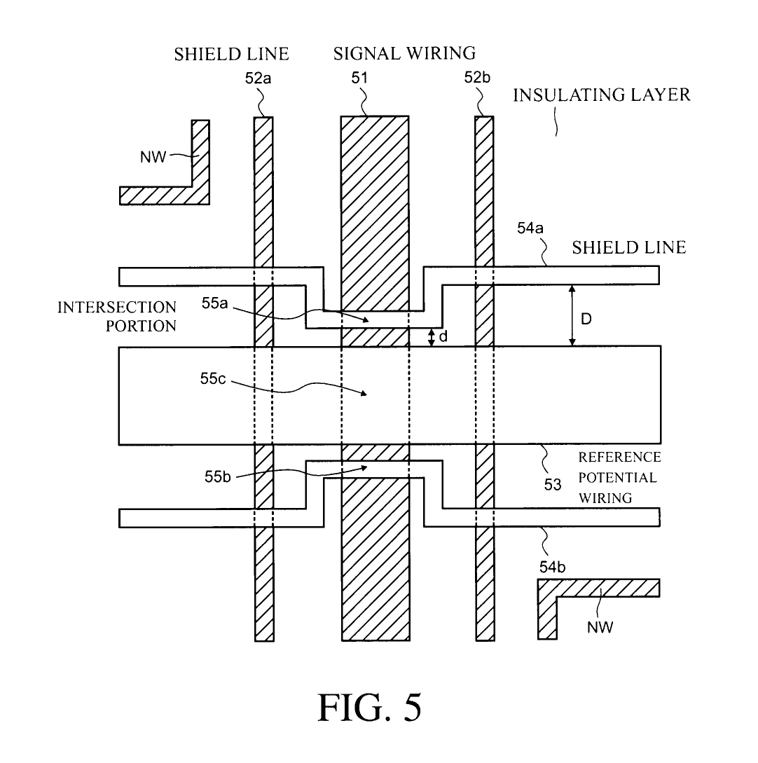

FIG. 5 is a layout chart showing a semiconductor device according to a fifth embodiment. FIG. 5 mainly shows an example of a reference potential wiring 53 (a reference wiring) and portions of the wiring related to coupling noise like as FIG. 1. In addition, FIG. 5 shows only the two wiring layers while omitting the insulating films.

The semiconductor device according to the fifth embodiment includes a signal wiring 51 and shield lines 52a, 52b, all of which are provided in the underlying wiring layer. The semiconductor device also includes a reference potential wiring 53 and shield lines 54a, 54b, all of which are provided in the upper wiring layer.

The signal wiring 51, the reference potential wiring 53, and the shield lines 52a, 52b, 54a, 54b according to the fifth embodiment have their respective functions and positional relationships on the layout which are similar to those in the first embodiment. Hence, no detailed description is given of the functions and the positions. The fifth embodiment is different from the first embodiment in which the shield lines 54a, 54b are provided to have U-shapes which project toward the reference potential wiring 53 in positions near intersection portions 55a, 55b of both the signal wiring 51 and the shield lines 54a, 54b, instead of being provided with larger wiring widths.

As shown in FIG. 5, the shield line 54a is provided to have a U-shape projecting toward the reference potential wiring 53 near the intersection portion 55a of both the shield line 54a and the signal wiring 51. To put it differently, the shield line 54a projects downward in FIG. 5. Hence, the shield line 54a is separated away from the reference potential wiring 53 by a smaller distance d near an intersection portion 55c than the distance D in other portions (i.e., d<D).

Likewise, the shield line 54b is provided to have a U-shape projecting toward the reference potential wiring 53 near the intersection portion 55b of both the shield line 54b and the signal wiring 51. To put it differently, the shield line 54b projects upward in FIG. 5. Hence, the shield line 54b is separated away from the reference potential wiring 53 by a smaller distance d near the intersection portion 55c than the distance D in the other portions (i.e., d<D).

As described above, the reference potential wiring 53 is separated away from each of the shield lines 54a, 54b by a narrower distance in the intersection portion 55c of both the signal wiring 51 and the reference potential wiring 53. Hence, the line of the electric force which would otherwise be directed from the signal wiring 51 to the reference potential wiring 53 can be directed to the shield lines 59a, 59b, and thus the coupling capacitance of both the signal wiring 51 and the reference potential wiring 53 caused by the sneak path effect can be reduced.

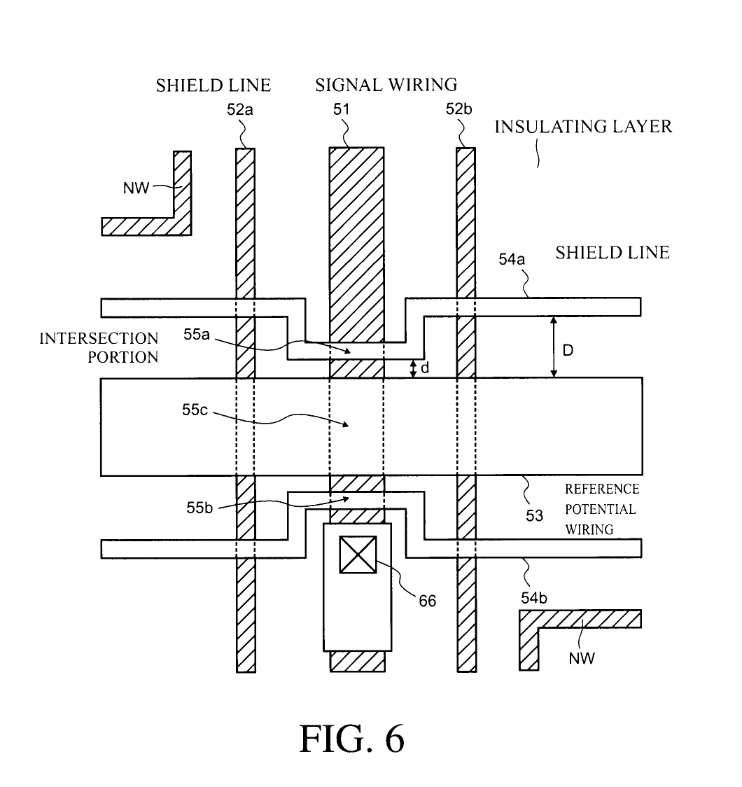

In addition, the formation of the U-shape shield lines 54a, 54b improves the degree of freedom of the layout because, as shown in FIG. 6 for example, a contact wiring 67 and a contact 66 with the signal wiring 51 in the underlying layer wiring layer can be provided in a space inside the U-shape shield line 54a or 54b.

According to the fifth embodiment, effects which are similar to those of the first embodiment can be obtained. In addition, it is possible to improve the degree of freedom of the wiring layout while reducing the layout area.

In the fifth embodiment, the shield lines 54a, 54b are provided respectively on the two sides of the reference potential wiring 53, but the embodiment is not limited to the above case. The embodiment is also applicable to only one of the shield lines.

In the fifth embodiment, the shapes of the shield lines 54a, 54b provided in the upper wiring layer are modified into U-shapes, but the embodiment is not limited only to the above-described configuration. Alternatively, the shapes of the shield lines 52a, 52b provided in the underlying wiring layer can be modified into U-shapes.

In addition, though the shapes of the shield lines 54a, 54b provided in the upper wiring layer are modified into U-shapes in the fifth embodiment, the modified shape does not have to be a U-shape. Any shape is acceptable as long as the shield line 54a, 54b are at least modified into such shapes which come close to the reference potential wiring 53 near the intersection portion 55a, 55b.

In the first to the fifth embodiments, the wiring layout of either the upper wiring layer or the underlying wiring layer is modified. However, the embodiments are not limited only to such configuration. The wiring layouts of both of the wiring layers can be modified independently of each other.

In the first to the fifth embodiments, each shield line is electrically connected to a fixed potential, but the embodiments are not limited only to such a configuration. For example, any wiring can be employed as long as the wiring can serve as a shield line immediately before and after a particular timing when the reference potential is referred to, that is, at a timing when the influence of the coupling noise at the intersection portion would cause a malfunction of a system.

In the first to the fifth embodiments, the wiring affected by the coupling noise is the reference potential wiring, but the embodiments are not limited only to such a premise. The embodiment is applicable to any wiring which can be affected by coupling noise at an intersection portion and can cause a malfunction of a system.

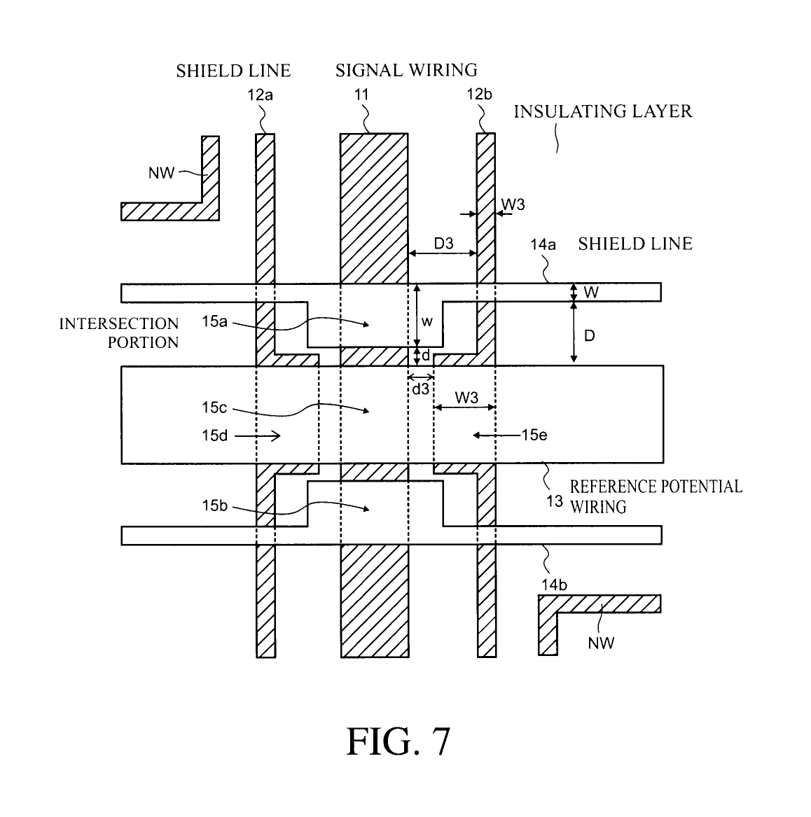

It is also possible to carry out a combination of the first embodiment and the second embodiment as shown in FIG. 7. For example, at the intersection portion 15C, the distance (d) between each shield line on the underlying layer and the signal wiring can be shortened and the distance (d) between the shield line on the upper layer and the reference potential wiring can be shortened at the same time. As a consequence, the influence of the coupling noise in the intersection portion can be reduced further.

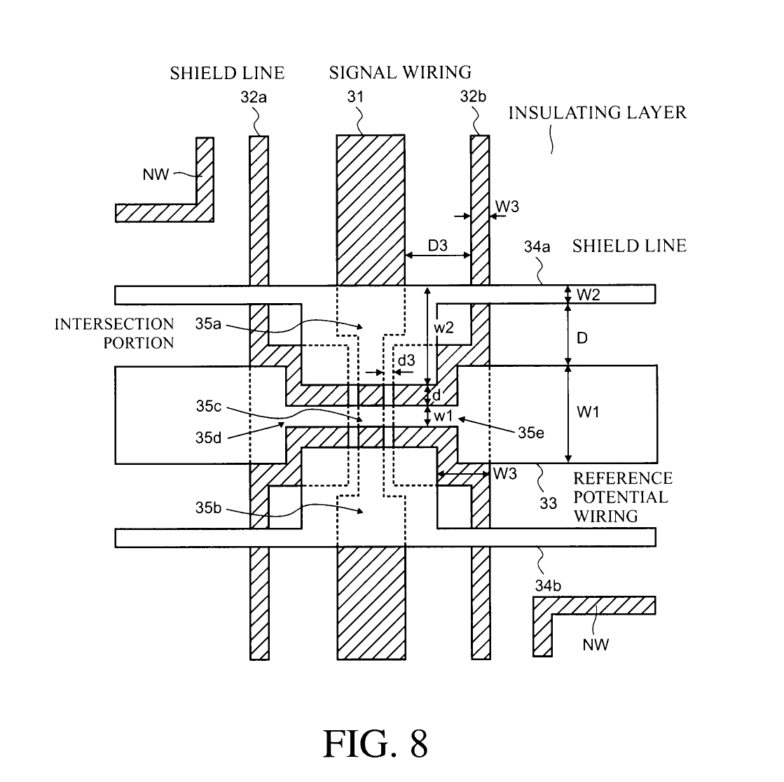

Embodiments can be carried out in a combination of the third embodiment and the fourth embodiment as shown in FIG. 8. For example, at the intersection portion 35C, it is also possible to reduce the distance (d3) between each shield line and the signal wiring in the underlying layer and the width of the signal wiring from the distance (D3), and to reduce the distance (d) between each shield line and the reference potential in the upper layer and the width of the reference potential wiring from the distance (D), at the same time. As a consequence, the influence of the coupling noise in the intersection portion can be reduced further.

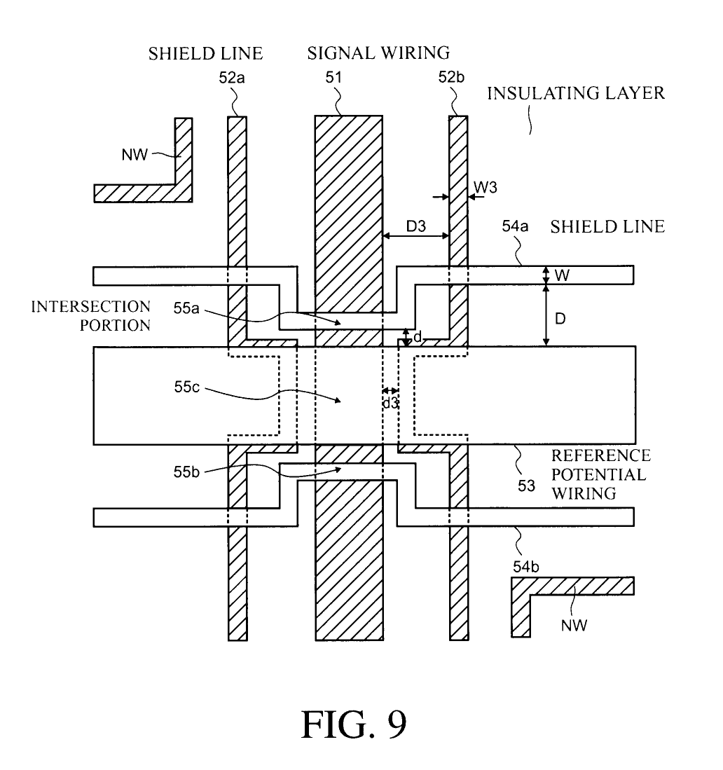

The configuration of the fifth embodiment can be applied to both of the wirings in the upper layer and the wirings in the underlying layer as shown in FIG. 9. For example, at the intersection portion 55C, each shield line is made to come close to the signal wiring in the underlying layer while each shield line is made to come close to the reference potential wiring in the upper layer. As a consequence, the influence of the coupling noise in the intersection portion can be reduced further. In addition, it is also possible to improve the degree of freedom of the wiring layout.

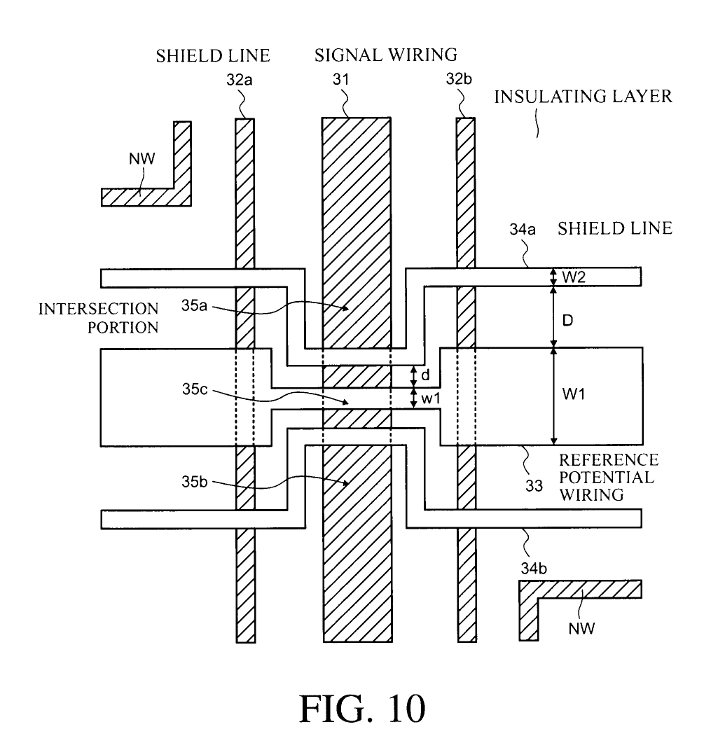

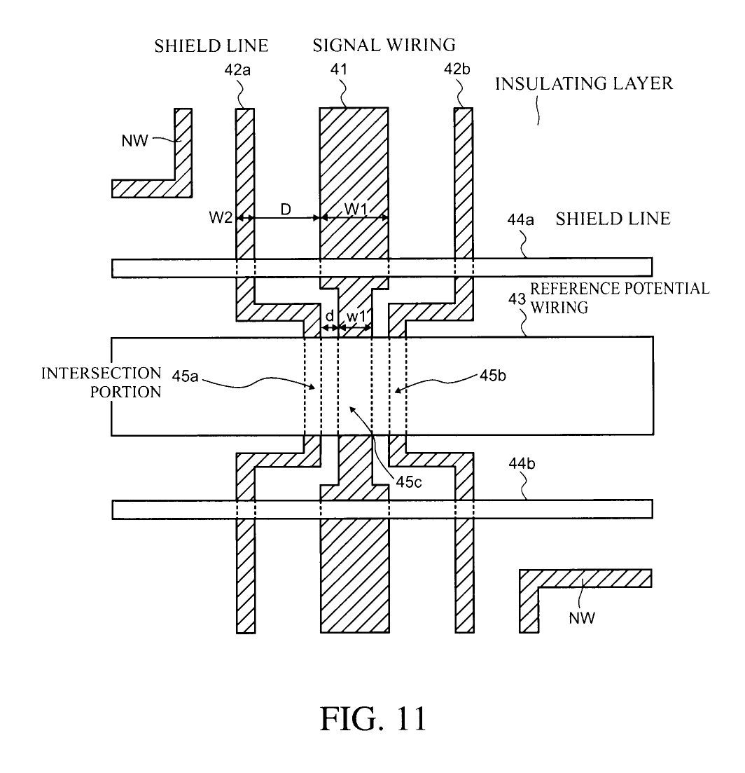

Embodiments can be carried out in a combination of the third embodiment and the fifth embodiment and a combination of the fourth embodiment and the fifth embodiment as shown in FIGS. 10, 11, respectively.

Moreover, the embodiments are applicable not only to the case where the reference potential wiring intersects the signal wiring but also to the case where the reference potential wiring intersects a high voltage wiring, and to the case where the signal wiring intersects the high voltage wiring.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first wiring provided in a first wiring layer along a first direction;
a second wiring provided in a second wiring layer along a second direction orthogonal to the first direction, the second wiring intersecting with the first wiring at a first intersect portion; and
a third wiring provided close to and along the second wiring in the second wiring layer, the third wiring intersecting with the first wiring at a second intersect portion;
wherein a distance between the second wiring in the first intersection portion and the third wiring in the second intersection portion is narrower than a distance between the second wiring another than the first intersection portion and the third wiring another than the second intersection portion.

2. The semiconductor device of claim 1, wherein
a width of the first intersect portion of the third wiring is wider than a width of the second intersect portion of the third wiring.

3. The semiconductor device of claim 2, wherein
a width of the first intersect portion of the second wiring is narrower than a width of the second intersect portion of the second wiring.

4. The semiconductor device of claim 1 wherein
the width of the second intersect portion of the third wiring is the same as the width of another portion of the third wiring.

5. The semiconductor device of claim 4, wherein
the third wiring has U-shape.

6. The semiconductor device of claim 5, wherein
a contact wiring electrically connecting to the first wiring is provided in a space inside the U-shape of the third wiring.

7. The semiconductor device of claim 5, wherein
the width of the first intersect portion of the second wiring is narrower than the width of the second intersect portion of the second wiring.

8. The semiconductor device of claim 1, further comprising:
a fourth wiring provided close to and along the first wiring provided in the first wiring layer, the fourth wiring intersecting with the second wiring at a third intersect portion.

9. The semiconductor device of claim 8, wherein
a distance between the fourth wiring in the third intersection portion and the first wiring in the first intersection portion is narrower than a distance between the fourth wiring another than the third intersection portion and the first wiring another than the first intersection portion.

10. The semiconductor device of claim 9, wherein
a width of the first intersect portion of the fourth wiring is wider than a width of the second intersect portion of the fourth wiring.

11. The semiconductor device of claim 11, wherein
the width of the first intersect portion of the first wiring is narrower than the width of the second intersect portion of the first wiring.

12. The semiconductor device of claim 9
wherein the width of the first intersect portion of the fourth wiring is the same as the width of another portion of the fourth wiring.

13. The semiconductor device of claim 12, wherein
the third wiring has U-shape.

14. The semiconductor device of claim 12, wherein
a contact wiring electrically connecting to the first wiring is provided in a space inside the U-shape of the third wiring.

15. The semiconductor device of claim 12, wherein
the width of the first intersect portion of the first wiring is narrower than the width of second intersect portion of the first wiring.

16. The semiconductor device of claim 12, wherein
the width of the first intersect portion of the second wiring is narrower than the width of the second intersect portion of the second wiring.

17. The semiconductor device of claim 8, wherein
both the third wiring and the fourth wiring act as a shield line to shield the first wiring and the second wiring.

18. The semiconductor device of claim 1, wherein
one of the first wiring and the second wiring is a signal wiring and the other is a reference potential line.
